(19) United States
(12) Patent Application Publication
(10) Pub. No.: US 2012/0105091 A1
(43) Pub. Date: May 3, 2012

(54) STACKED FPGA BOARD FOR SEMICONDUCTOR VERIFICATION

(76) Inventors: Il Ho Kook, Seoul (KR); Jong Jin Park, Gyeonggi-do (KR); Chang Suc Han, Incheon (KR); Sung Tae Kang, Seoul (KR)

(21) Appl. No.: 13/377,591

(22) PCT Filed: Jun. 9, 2010
(86) PCT No.: PCT/KR10/03686

§ 371 Date: Jan. 6, 2012

(30) Foreign Application Priority Data
Jun. 12, 2009 (KR) 10-2009-0052451

(51) Int. Cl. G01R 31/26

(52) U.S. Cl. 324/756.07

(57) ABSTRACT

Disclosed herein is an FPGA board assembly for inspecting a semiconductor, the FPGA board assembly being a programmable logic device (PLD) board for inspecting a semiconductor product design, comprising: one or more FPGA boards, each including an FPGA chip provided with a logic circuit for inspecting a semiconductor and a plurality of connectors for inputting/outputting signals; and a switching board including connectors corresponding to the connectors and selectively connecting signals between the FPGA boards, wherein the one or more FPGA boards and the switching board are connected with each other in the form of a laminate by their respective connectors to inspect a semiconductor product design. The FPGA board assembly is advantageous in that boards can be easily connected with each other and in that various problems, such as difficulties of wiring design, the spatial restriction and the like, can be solved.

### TECHNICAL FIELD

The present invention relates to an FPGA board assembly for inspecting a semiconductor, and, more particularly, to an FPGA board assembly for inspecting a semiconductor, which has a flexible connecting structure that can connect a plurality of FPGA boards.

### BACKGROUND ART

Nowadays, as the scale of system semiconductor design becomes large, it is necessary to inspect large-scale semiconductor product designs, for which FPGA devices are used.

An FPGA (Field Programmable Gate Array) is a semiconductor device including programmable logic factors and programmable internal lines. The programmable logic factors AND, OR, XOR, NOT, and combinations thereof, wherein programming can be performed by reproducing basic logic gate functions such as combinations of complicated decoding functions and calculating functions. Most FPGAs also include memory factors, such as simple flip flops, perfect memory blocks and the like, in addition to the programmable logic factors (referred to as logic blocks).

A PLD (Programmable Logic Device), which is used to inspect a semiconductor product design using the FPGA, must use a highly-integrated FPGA depending on the increase in the size of a circuit to be stored in the PLD. This highly-integrated FPGA is a very high-priced semiconductor part, and must be reused. After finishing an inspection process, a PCB, which was configured to inspect a semiconductor product design, must be dismantled such that the high-priced FPGA can be reused. However, at the time of dismantling the PCB, there is a problem in that the PCB breaks down because an FPGA embedded with a high-capacity logic circuit is a highly-integrated package part having one thousand pins or more.

A conventional PCB, which is used in a system for inspecting a semiconductor product design, is fabricated by arranging a plurality of highly-integrated FPGA devices each having compact input output pins on a two-dimensional plane and wiring these FPGA devices. When a plurality of highly-integrated FPGA devices each having compact input output pins are arranged on a two-dimensional plane, the wiring between the FPGA devices becomes very long, thus deteriorating overall system performance.

As described above, the restrictions on the arrangement and wiring of FPGA devices do not take into consideration the configuration requirements of a PCB used in a system for inspecting a semiconductor product design, the wiring of which between FPGA devices is extensive. Further, during the process of inspecting the semiconductor product design, the semiconductor product design is frequently changed, but a high-density PCB cannot be revised because the arrangement and wiring are fixed, so that it is required to fabricate the PCB again, which is very inefficient, and, when the PCB is fabricated again, there is great concern that the PCB will be rendered out of order in the course of dismantling and fixing high-priced FPGAs.

Further, the restrictions on the wiring of FPGA devices, which did not take into consideration the configuration requirement of the PCB, can be solved with the use of additional cables, but the number of cables is restricted. In order to use dense cables, it is required to fabricate a connector having a specific structure. However, when the connector is used, the length of the cables cannot be easily adjusted, and signal distortion is caused, so that a method of assuring the electrical characteristics of the connector is required.

Further, since a conventional PCB, in which FPGA devices are arranged on a two-dimensional plane, occupies a very large plane area in order to assure the region for arranging and wiring FPGA devices, there are various problems, such as a spatial restriction and the like.

### DISCLOSURE

### Technical Problem

Accordingly, the present invention has been devised to solve the above-mentioned problems, and an object of the present invention is to provide an FPGA board assembly for inspecting a semiconductor, which can flexibly connect a plurality of FPGA boards using a common connector.

Another object of the present invention is to provide an FPGA board assembly for inspecting a semiconductor, which can easily control the flow of signals by connecting a switching board between FPGA boards using a common connector.

A further object of the present invention is to provide an FPGA board assembly for inspecting a semiconductor, which can solve the problem of spatial restriction by arbitrarily separating input and output signals from vertically-connected FPGAs such that a plurality of FPGA boards can be laminated.

Still another object of the present invention is to provide an FPGA board assembly for inspecting a semiconductor, which can improve performance by maintaining uniform and short bus-type wiring having a bit width larger than that of wirings running between the FPGAs arranged on a plane.

### Technical Solution

In order to accomplish the above objects, an aspect of the present invention provides an FPGA board assembly for inspecting a semiconductor, the FPGA board assembly being a programmable logic device (PLD) board for inspecting a semiconductor product design, including: one or more FPGA boards, each including an FPGA chip provided with a logic circuit for inspecting a semiconductor and a plurality of connectors for inputting/outputting signals; and a switching board including connectors corresponding to the connectors and selectively connecting signals between the FPGA boards, wherein the one or more FPGA boards and the switching board are connected in the form of a laminate by their respective connectors to inspect a semiconductor product design.

Here, the FPGA board and the switching board may be provided with eight of the connectors, respectively.

Further, each of the FPGA boards may be provided with a power input unit.

Further, each of the connectors may have 180 pins.

Further, the connectors of the FPGA board may correspond to the connectors of the switching board such that the FPGA board and the switching board are connected by their respective connectors.

The FPGA board assembly may further include: an extension board which includes connectors disposed between the connectors for connecting the FPGA board and the switching board to output signals to the outside and which includes input/output pins provided in the connectors.

The FPGA board assembly may further include: a base board which includes connectors for mounting the FPGA board and the switching board, on which accompanying boards including a display board and a memory board are mounted.

A further aspect of the present invention provides an FPGA board assembly for inspecting a semiconductor, the FPGA board assembly being a programmable logic device (PLD) board for inspecting a semiconductor product design, including: two or more FPGA boards, each including an FPGA chip provided with a logic circuit for inspecting a semiconductor and a plurality of connectors for inputting/outputting signals, wherein the two or more FPGA boards are connected with each other by their respective connectors to connect signals between the FPGA boards.

The FPGA board assembly may further include: a switching board which includes connectors corresponding to the connectors of each of the FPGA boards and which is disposed between the FPGA boards to selectively connect signals therebetween.

### Advantageous Effects

As described above, the FPGA board assembly of the present invention is advantageous in that high-priced FPGA devices are not dismantled from a PCB, and FPGA boards are connected by a laminating method, so the FPGA devices are not damaged, and revision and modification is very easy.

Further, the FPGA board assembly of the present invention is advantageous in that it can flexibly connect a plurality of FPGA boards and can more easily inspect a semiconductor using a switching board.

Further, the FPGA board assembly of the present invention is advantageous in that it can solve the problem of spatial restriction by a vertically-arranged multilayer structure, so it can be used in a narrow space.

Further, the FPGA board assembly of the present invention is advantageous in that it can solve the problem of the wiring being complicated, the problem occurring when designing a conventional two-dimensional FPGA board.

### DESCRIPTION OF DRAWINGS

FIG. 1 is a schematic plan view showing a conventional FPGA board for inspecting a semiconductor;

FIG. 2 is a schematic perspective view showing an FPGA board assembly for inspecting a semiconductor according to the present invention;

FIG. 3 is a schematic perspective view showing an FPGA board of the FPGA board assembly for inspecting a semiconductor according to the present invention;

FIG. 4 is a schematic perspective view showing a switching board of the FPGA board assembly for inspecting a semiconductor according to the present invention;

FIGS. 5 to 7 are sectional views showing the connection state of the FPGA board assembly for inspecting a semiconductor according to the present invention;

FIGS. 8 and 9 are perspective views showing extension boards of the FPGA board assembly for inspecting a semiconductor according to the present invention;

FIG. 10 is a perspective view showing an adaptor board of the FPGA board assembly for inspecting a semiconductor according to the present invention; and

FIG. 11 shows a plan view and sectional view of the FPGA board assembly provided with a base board.

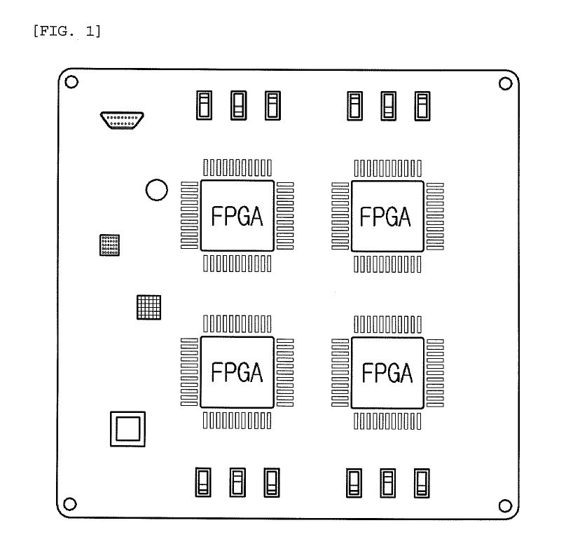

### DESCRIPTION OF THE REFERENCE NUMERALS IN THE DRAWINGS

100: FPGA board

110: FPGA

120: connector

200: switching board

210: switching device

220: connector

300: extension board

400: adaptor board

500: base board

### BEST MODE

Hereinafter, preferred embodiments of an FPGA board assembly for inspecting a semiconductor according to the present invention will be described in detail with reference to the accompanying drawings.

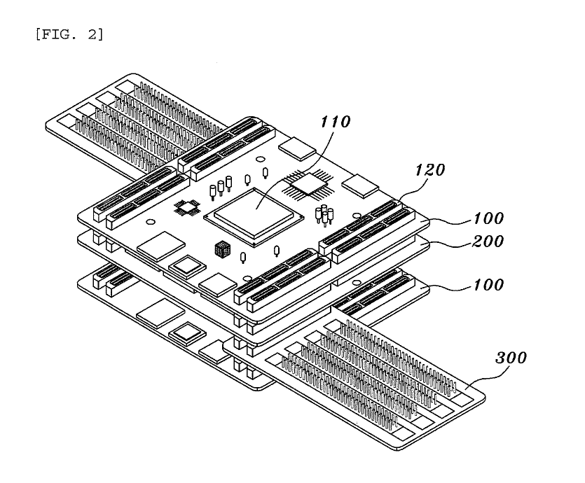

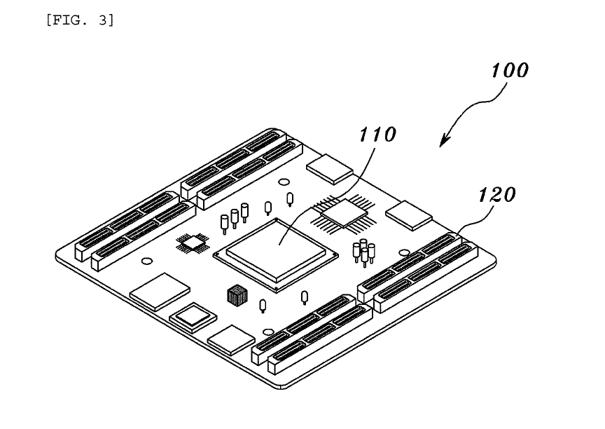

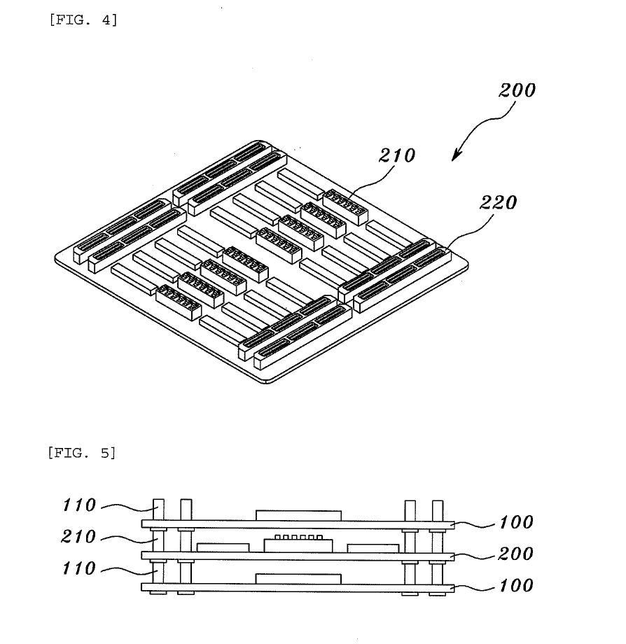

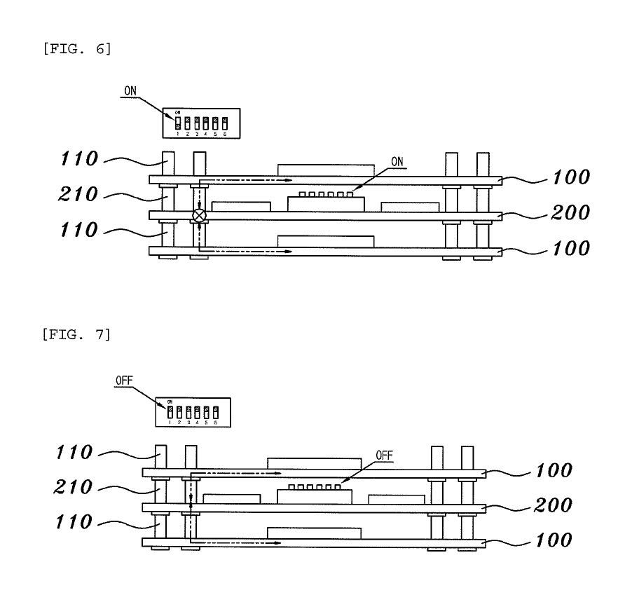

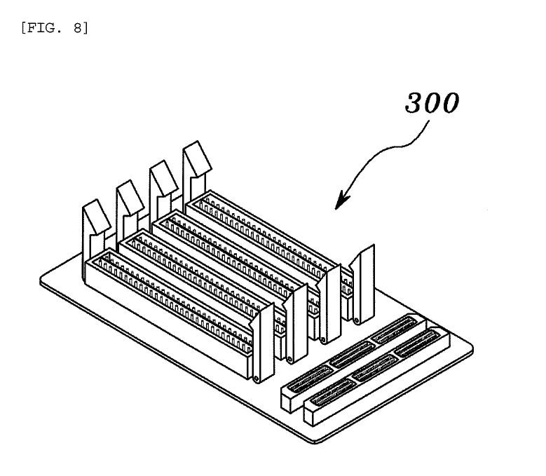

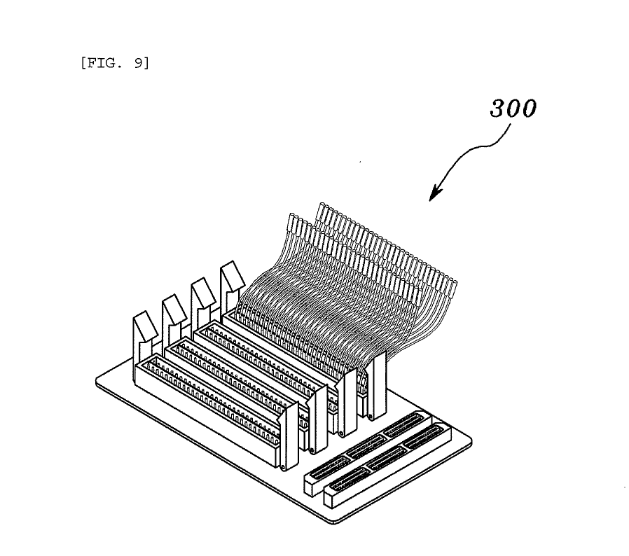

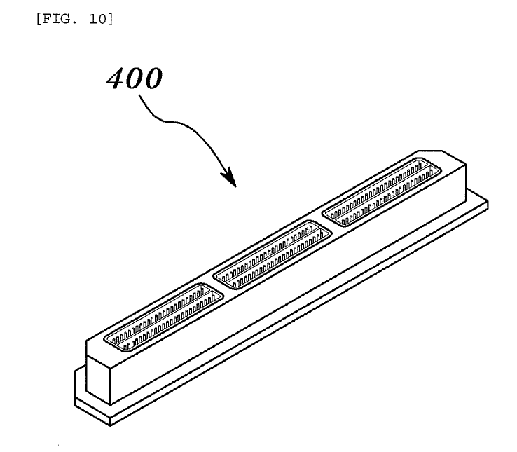

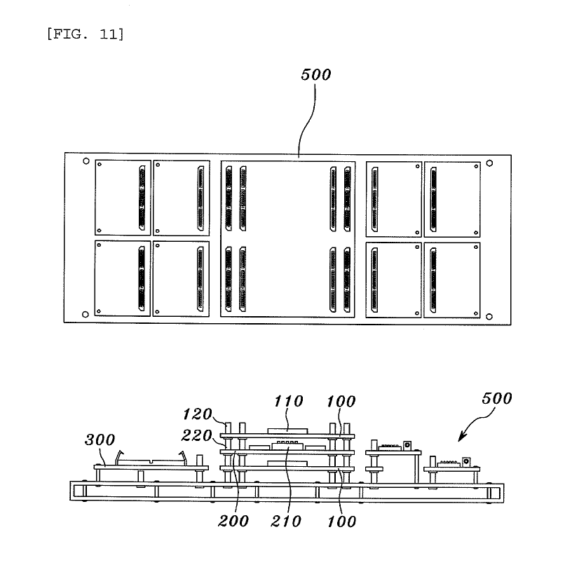

FIG. 2 is a schematic perspective view showing an FPGA board assembly for inspecting a semiconductor according to the present invention, FIG. 3 is a schematic perspective view showing an FPGA board of the FPGA board assembly for inspecting a semiconductor according to the present invention, FIG. 4 is a schematic perspective view showing a switching board of the FPGA board assembly for inspecting a semiconductor according to the present invention, FIGS. 5 to 7 are sectional views showing the connection state of the FPGA board assembly for inspecting a semiconductor according to the present invention, FIGS. 8 and 9 are perspective views showing extension boards of the FPGA board assembly for inspecting a semiconductor according to the present invention, FIG. 10 is a perspective view showing an adaptor board of the FPGA board assembly for inspecting a semiconductor according to the present invention, and FIG. 11 shows a plan view and a sectional view of the FPGA board assembly provided with a base board.

The present invention provides an FPGA board assembly for inspecting a semiconductor, the FPGA board assembly being a programmable logic device (PLD) board for inspecting a semiconductor product design, including: one or more FPGA boards, each including an FPGA chip provided with a logic circuit for inspecting a semiconductor and a plurality of connectors for inputting/outputting signals; and a switching board including connectors corresponding to the connectors and selectively connecting signals between the FPGA boards, wherein the one or more FPGA boards and the switching board are connected with each other in the form of a laminate by their respective connectors to inspect a semiconductor product design.

The FPGA board 100, which is a PCB mounted with a highly-integrated FPGA device 110, ascertains whether or not a semiconductor product design operates correctly after a program designed to inspect a semiconductor is written to the FPGA device 110. In this case, as the capacity of a logic circuit necessary for ascertaining whether or not the semiconductor product design operates correctly becomes large, a plurality of FPGA boards 100 is used. In the present invention, each of the FPGA boards 100 is provided with a plurality of commonly-standardized connectors 120.

The connectors 120 are used to connect the plurality of the FPGA boards 100 with the subsequent switching board 200. The pins of the connectors 120 are electrically connected with the pins of the FPGA device 110.

Here, the connectors 120, which are vertically-connectable connectors, are connected to each other such that they correspond to each other. In the present invention, eight connectors, each having 180 pins, are used in one FPGA board, so that the signal input/output of 1440 pins can be secured.

Further, each of the FPGA boards includes a power input unit (not shown) for receiving power, a plurality of parts for signal processing, and a switch-type code setting unit (not shown) for identifying the code of each of the FPGA boards.

The switching board 200, which is a board for switching signals at the time the plurality of FPGA boards are connected, is provided with connectors 220 having the same standard as the connectors 120 provided on each of the FPGA boards.

The switching board 200 is provided with a plurality of switching devices 210, and the switching devices 210 can be manually controlled by manually switching the switching devices 210 or can be automatically controlled programmatically. In the present invention, for example, dip switch devices are used as the switching devices 210 in order to manually control the switching devices 210, but the present invention is not limited thereto.

In this case, as in the FPGA board, the switching devices 210 are configured to correspond to the eight connectors 220 provided on the switching board 200, thus blocking the signal transmitted through each of the connectors 220. Here, the connectors 220 provided on the switching board 200 are different from the connectors 120 provided on each of the FPGA board in that the upper and lower pins of the connectors 220 are connected to each other via the switching devices 210, but the upper and lower pins of connectors 120 are directly connected to each other.

Therefore, if necessary, the signals of the FPGA device 110 can be partially blocked by the switching devices 210, thus controlling the flow of signals between the boards.

It is preferred that the number of FPGA boards used in the present invention be two.

Assuming that four FPGA boards are designated as first, second, third and fourth FPGA boards in order of laminating the four FPGA boards, signals are connected between the first FPGA board and the second FPGA board through the upper and lower connectors, but these connectors cannot be used to connect signals between the third FPGA board and the fourth FPGA board. However, when a signal connection is cut by disposing the switching board 200 between the second FPGA board and the third FPGA board, all of the input and output pins of the third FPGA board can be freely used without regard to whether or not they are used in the FPGA boards disposed below the third FPGA board. When the switching board 200 is disposed between adjacent FPGA boards, necessary signals therebetween can be connected, and unnecessary signals therebetwen can be separated.

Further, the switching board 200 is configured by programming to arbitrarily connect or block signal lines, and can thus be easily modified or reused.

The FPGA boards 100 and the switching board 200 can be connected by the connectors 120 and 220 in the form of a laminate.

Meanwhile, the FPGA board assembly of the present invention further includes an extension board 300 which can extend signal lines such that the signals processed between boards can be externally monitored. The extension board 300 is disposed between the connectors for connecting the FPGA boards 100 and the switching board 200. This extension board 300 is provided with a plurality of connecting terminals 310 having the same standard as that of the connectors, and can output signals to the outside through the connecting terminals 310.

Each of the connecting terminals 310 is provided with 180 pins corresponding to those of the connectors. For the purpose of manual extension easiness, the connecting terminals 310 may be larger than the connectors. Electric wires may be connected to these connection terminals 310.

Moreover, the FPGA board assembly of the present invention further includes an adaptor board 400 for maintaining the gap between the FPGA boards or the gap between the FPGA board and the switching board at the time of connecting the extension board 30. The adaptor board 400 serves to maintain the gap between the FPGA boards or the gap between the FPGA board and the switching board at the time of connecting the extension board 30 and to connect the connectors, and is provided with connectors having the same standard as those of the FPGA boards and the switching board.

Meanwhile, the FPGA board assembly of the present invention further includes a base board 500 on which the FPGA boards and the switching board are mounted, and on which accompanying boards necessary for inspecting a final semiconductor product design can be mounted. The base board 500 is also provided thereon with commonly-standardized connectors in order to mount the FPGA boards and the switching board. Although not shown, the connectors of the base board 500 are used to connect the accompanying boards, such as a display board, a memory board, an audio board, a controller board and the like, which are necessary for the inspection of the final semiconductor product design. The base board 500 is provided thereon with a plurality of connectors because the accompanying boards are connected by the commonly-standardized connectors.

According to the FPGA board assembly of the present invention, FPGA boards provided with commonly-standardized connectors are laminated and connected with each other, and the flow of signals can be freely controlled by the switching board, so that the problem of a spatial restriction can be solved by a vertical laminating method which can also realize a flexible connection.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Therefore, it will be considered that simple modifications, additions, substitutions and equivalents of the present invention belong to the scope of the present invention.

1. An FPGA board assembly for inspecting a semiconductor, the FPGA board assembly being a programmable logic device (PLD) board for inspecting a semiconductor product design, comprising:
one or more FPGA boards, each including an FPGA chip provided with a logic circuit for inspecting a semiconductor and a plurality of connectors for inputting/outputting signals; and
a switching board including connectors corresponding to the connectors and selectively connecting signals between the FPGA boards,
wherein the one or more FPGA boards and the switching board are connected in the form of a laminate by their respective connectors so that a semiconductor product design can be inspected.

2. The FPGA board assembly for inspecting a semiconductor according to claim 1, wherein the FPGA board and the switching board are provided with eight of the connectors, respectively.

3. The FPGA board assembly for inspecting a semiconductor according to claim 1, wherein each of the FPGA boards is provided with a power input unit.

4. The FPGA board assembly for inspecting a semiconductor according to claim 1, wherein each of the connectors has 180 pins.

5. The FPGA board assembly for inspecting a semiconductor according to claim 1, wherein the connectors of the FPGA board correspond to the connectors of the switching board such that the FPGA board and the switching board are connected by their respective connectors.

6. The FPGA board assembly for inspecting a semiconductor according to claim 1, further comprising: an extension board which includes connectors disposed between the connectors for connecting the FPGA board and the switching board to output signals to outside and which includes input/output pins provided in the connectors.

7. The FPGA board assembly for inspecting a semiconductor according to claim 1, further comprising: a base board which includes connectors for mounting the FPGA board and the switching board, on which accompanying boards including a display board and a memory board are mounted.

8. An FPGA board assembly for inspecting a semiconductor, the FPGA board assembly being a programmable logic device (PLD) board for inspecting a semiconductor product design, comprising:
two or more FPGA boards, each including an FPGA chip provided with a logic circuit for inspecting a semiconductor and a plurality of connectors for inputting/outputting signals,
wherein the two or more FPGA boards are connected with each other by their respective connectors to connect signals between the FPGA boards.

9. The FPGA board assembly for inspecting a semiconductor according to claim 8, further comprising: a switching board which includes connectors corresponding to the connectors of each of the FPGA boards and which is disposed between the FPGA boards to selectively connect signals therebetween.

10. The FPGA board assembly for inspecting a semiconductor according to claim 2, wherein each of the connectors has 180 pins.

11. The FPGA board assembly for inspecting a semiconductor according to claim 2, wherein the connectors of the FPGA board correspond to the connectors of the switching board such that the FPGA board and the switching board are connected by their respective connectors.
